(19) United States
(12) Patent Application Publication
(10) Pub. No.: US 2006/0246616 A1
(43) Pub. Date: Nov. 2, 2006

(54) Structure of laser diode and method of manufacturing the same

(75) Inventors: Wei Chang, San Chung City (TW); Yi-Te Chen, San Chung City (TW)

Correspondence Address: TROXELL LAW OFFICE PLLC, SUITE 1404, 5205 LEESBURG PIKE, FALLS CHURCH, VA, 22041, US

(73) Assignee: Unity Opto Technology Co., Ltd.

(21) Appl. No.: 11/115,318

(22) Filed: Apr. 27, 2005

(51) Int. Cl. H01L 21/00

(52) U.S. Cl. 438/26

(57) ABSTRACT

A laser diode and a manufacture method thereof are disclosed. The method of manufacturing the laser diode comprises the steps of: 1. coupling a photo diode chip with one of a plurality of pins on a frame; 2. coupling and overlapping a laser diode chip with the photo diode chip; 3. bonding the laser diode chip and the photo diode chip to the other pins on the frame by use of conducting wires; 4. using a housing having an opening, a notch, and a mounting chamber for holding the pins to complete the assembly of the laser diode; and 5. cutting off connected portions among the pins to obtain the laser diode. Be means of the simplified manufacture process, the laser diode is suitable for mass production and the production cost is substantially reduced.

### FIELD OF THE INVENTION

The present invention relates to a structure suitable for mass production and a method of manufacturing this structure for simplifying process and substantially reducing production cost, and more particularly to a laser diode and a method of manufacturing this laser diode.

### BACKGROUND OF THE INVENTION

The photoelectric industry relates to a field that couples the electronics with the optics, wherein the light source for the fiber communication is mainly a light emitting diode or a laser diode. The light emitting diode includes the advantages of easy use and low production cost since its driving and compensation circuits are simpler. Accordingly, the light emitting diode is suitable for short distance transmission. The laser diode has the advantages of high output power, fast transmission speed, small light-emitting angle, and narrower spectrum (smaller chromatic dispersion) so it is more suitable for middle and long distances.

Although the applicable scope of the laser diode is very widespread, its still needs very careful and attentive manufacture process, high technology level, high-priced production equipments, and low-priced devices. As shown in FIG. 1, the conventional laser diode provides a base A on which two openings, a trench A1, and a pillar A2 are mounted. Each opening is coupled with a pin B, and a pin A21 is extended from the bottom of the pillar A2. A layer of adhesive is spread on the trench A1, and then a photo diode chip C is adhered to the adhesive layer. Thereafter, another laser diode chip D is bonded to the pillar A2 and mounted perpendicular to the photo diode chip C at 300 degrees centigrade. Finally, these two chips are covered by a metal cover E having a glass window E1 on its top.

The manufacture process of the conventional laser diode is very complex. The major drawback of the conventional laser diode consists in that the mounting positions and bonding methods of the photo diode and the laser diode are different from one another and the substrate must be rotated to be lain down so the manufacture speed is slow.

Accordingly, the present invention provides a laser diode suitable for mass production for simplifying the manufacture process and reducing the production cost

### SUMMARY OF THE INVENTION

It is a main object of the present invention to provide a method of manufacturing a laser diode for simplifying the manufacture process and reducing the production cost.

It is another object of the present invention to provide a laser diode suitable for mass production.

It is a further object of the present invention to provide a laser diode with convenient manufacture process and improved yield.

In order to achieve the aforementioned object, the method of manufacturing the laser diode of the present invention comprises the steps of: 1. coupling a photo diode chip with one of a plurality of pins on a frame; 2. coupling and overlapping a laser diode chip with the photo diode chip; 3. bonding the laser diode chip and the photo diode chip to the other pins on the frame by use of conducting wires; 4. using a housing having an opening, a notch and a mounting chamber for holding the pins to complete the assembly of the laser diode; and 5. cutting off connected portions among the pins to obtain the laser diode.

Be means of the simplified steps, the laser diode is suitable for mass production to substantially reduce the production cost.

The aforementioned aspects and advantages of the present invention will be readily clarified in the description of the preferred embodiments and the enclosed drawings of the present invention.

### BRIEF DESCRIPTION OF THE DRAWINGS

FIG. 1 is a schematic exploded view showing partial devices of the conventional laser diode.

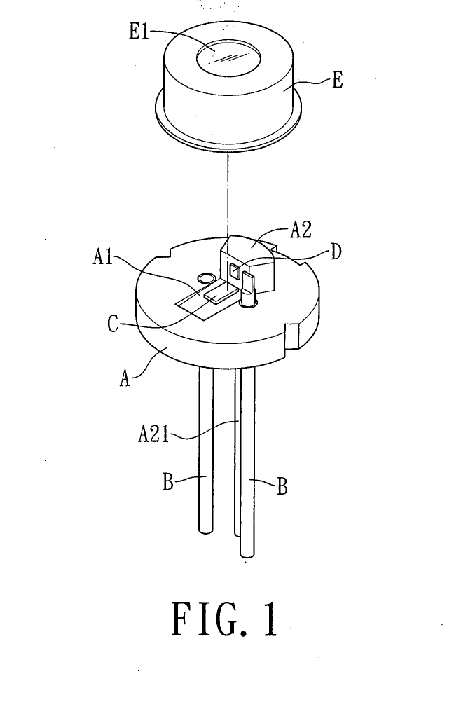

FIG. 2 shows a manufacture process of the present invention.

FIG. 3 is a schematic view showing that two chips are coupled with the frame in accordance with the present invention.

FIG. 4 is a schematic view showing the step of holding the frame by use of the housing in accordance with the present invention.

FIG. 5 is schematic cross-sectional view showing the preferred embodiment of the present invention.

FIG. 6 shows another manufacture process of the present invention.

### DETAILED DESCRIPTION OF THE PREFERRED EMBODIMENT

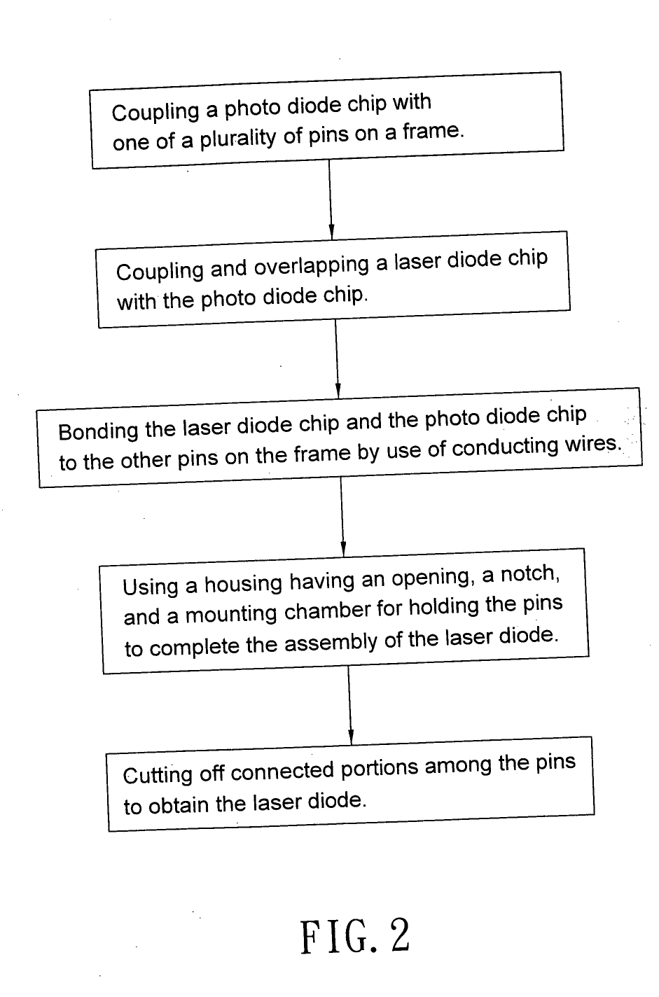

Referring to FIG. 2, a manufacture process of the present invention comprises the steps of:

1. coupling a photo diode chip with one of a plurality of pins on a frame;

2. coupling and overlapping a laser diode chip with the photo diode chip;

3. bonding the laser diode chip and the photo diode chip to the other pins on the frame by use of conducting wires;

4. using a housing having an opening, a notch and a mounting chamber for holding the pins to complete the assembly of the laser diode; and

5. cutting off connected portions among the pins to obtain the laser diode.

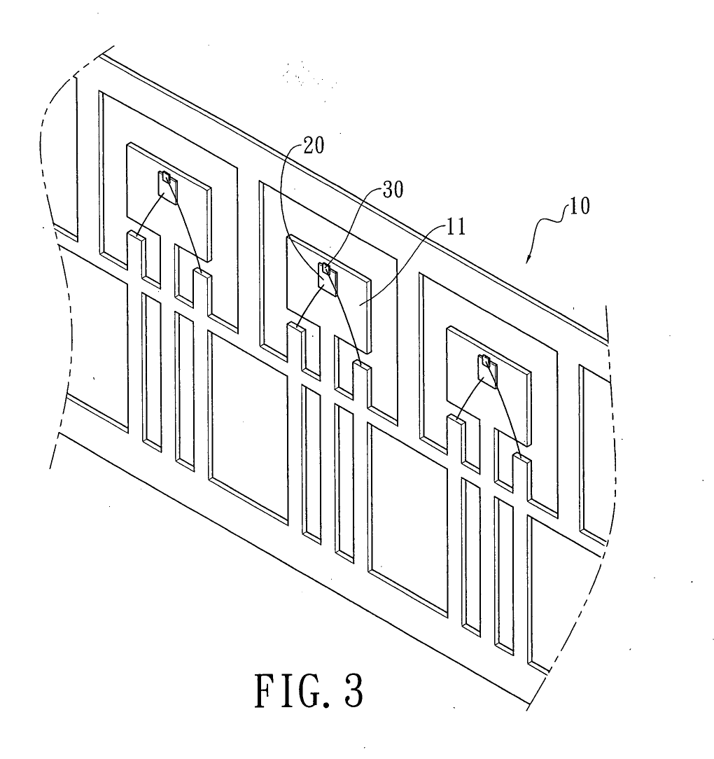

During the practical manufacture process, a plurality of photo diode chips 20 are coupled with the corresponding pins mounted on an uncut frame 10. The frame 10 disclosed in this preferred embodiment provides three connected pins, wherein the central pin further comprises a large area connecting portion 11 on its top, as shown in FIG. 3. Since these structures are identical, only a single structure is recited for explanation. The photo diode chip 20 is glued to the large area connecting portion 11 by use of an adhesive layer. Next, another laser diode chip 30 is partially overlapped and coupled with the photo diode chip 20 at 300 degrees centigrade to partially overlap and couple these chips 20, 30 with one another. Thereafter, the chips 20, 30 are bonded to the other pins on the frame 10 by use of conducting wires.

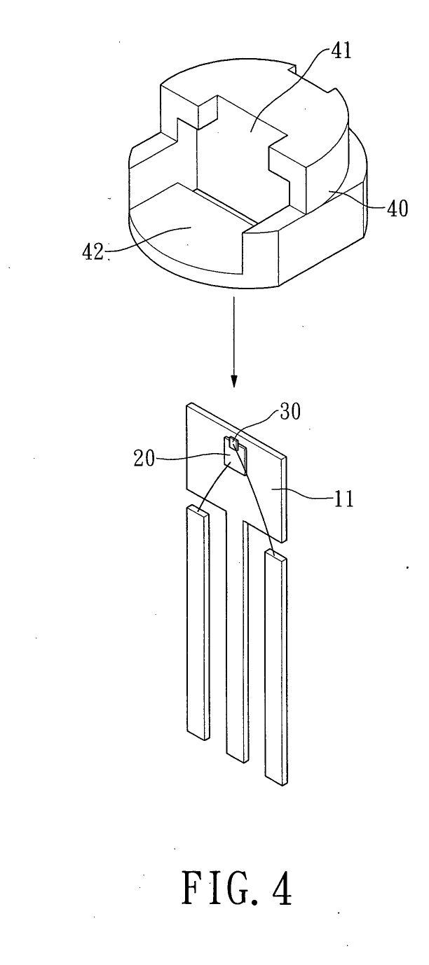

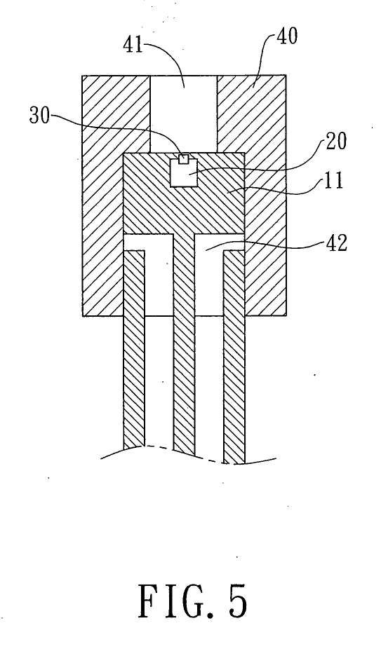

Referring to FIG. 4 and FIG. 5, a housing 40 having an opening 41, a notch 42, and a mounting chamber is put to use for holding the bonded chips 20, 30 and the tops of the pins from top to bottom such that these three pins including the large area connecting portions 11, these two chips 20, 30, and the conducting wires are held inside the mounting chamber, and the manufacture of the uncut laser diodes is thus completed. After the uncut frame 10 and the connected portions between these three pins are cut off, numerous laser diodes are obtained. Consequently, it is suitable for mass production.

After the obtained laser diode is connected with a power supply, the laser diode chip 30 emits the laser light from its front end and rear end both. The laser light emitted from the front end is emitted outward through the opening 41. The laser light emitted from the rear end is received by the photo diode chip 20 for feedback.

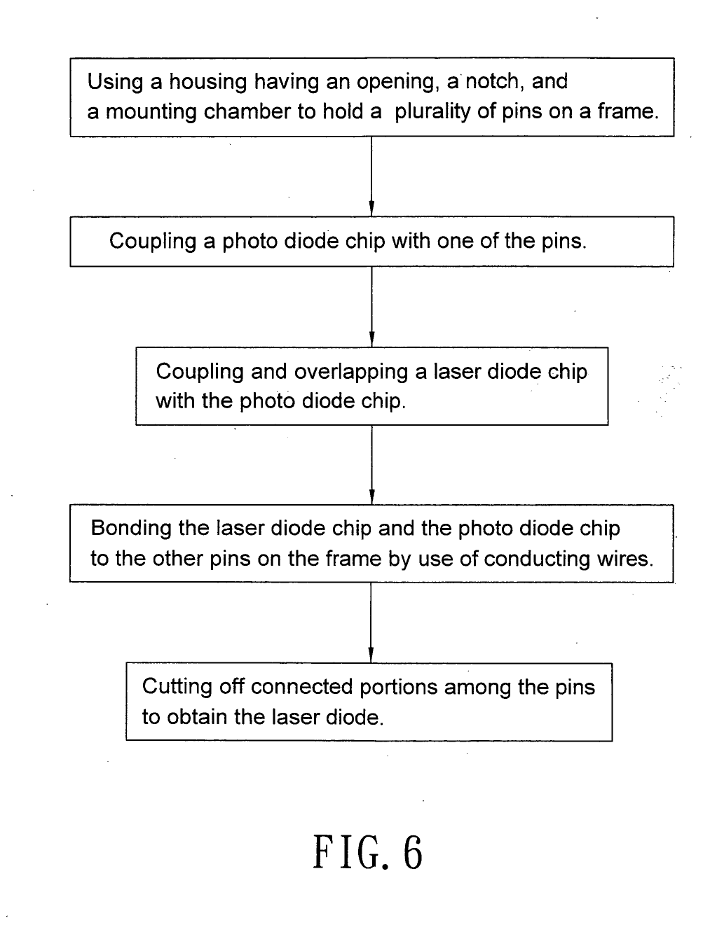

Referring further to FIG. 6, another manufacture process of the present invention comprises the steps of:

1. using a housing having an opening, a notch, and a mounting chamber to hold a plurality of pins on a frame;

2. coupling a photo diode chip with one of the pins;

3. coupling and overlapping a laser diode chip with the photo diode chip;

4. bonding the laser diode chip and the photo diode chip to the other pins on the frame by use of conducting wires; and

5. cutting off connected portions among the pins to obtain the laser diode.

From the above-mentioned description it is apparent that the structure and manufacture method of the present invention has the following advantages in which:

1. These two chips (photo diode chip and laser diode chip) are overlapped and mounted on the frame so the coupling positions of these two chips are changed and the manufacture process is thus further simplified to efficiently improve the complicated manufacture process of the conventional laser diode in which one chip is first coupled with the base and then the base is rotated to be lain down to couple with another chip.

2. The production cost is substantially reduced since the manufacture of the present invention is simple, fast, and suitable for mass production. Accordingly, the produced laser diode is provided with stable quality and improved yield.

On the basis of the aforementioned description, it is apparent that the present invention can achieve the expected purposes. The present invention satisfies all requirements for a patent and is submitted for a patent.

While the preferred embodiment of the invention has been set forth for the purpose of disclosure, modifications of the disclosed embodiment of the invention as well as other embodiments thereof may occur to those skilled in the art. Accordingly, the appended claims are intended to cover all embodiments, which do not depart from the spirit and scope of the invention.

What the invention claimed is:

1. A method of manufacturing a laser diode comprising the steps of:
a. coupling a photo diode chip with one of a plurality of pins on a frame;
b. coupling and overlapping a laser diode chip with the photo diode chip;
c. bonding the laser diode chip and the photo diode chip to the other pins on the frame by use of a plurality of conducting wires;
d. using a housing having an opening and a mounting chamber for holding the pins to complete the assembly of the laser diode; and
e. cutting off connected portions among the pins to obtain the laser diode.

2. A structure of a laser diode comprising:
a frame having three pins, wherein one of the pins has a large area connecting portion;
a photo diode chip coupled with the large area connecting portion;
a laser diode chip coupled and overlapped with the photo diode chip;
two conducting wires for bonding the laser diode chip and the photo diode chip to the other pins on the frame; and
a housing having an opening and a mounting chamber for holding the frame to allow the laser diode chip to emit the light through the opening.

3. A method of manufacturing a laser diode comprising the steps of:
a. using a housing having an opening, a notch, and a mounting chamber to hold a plurality of pins on a frame;
b. coupling a photo diode chip with one of the pins;
c. coupling and overlapping a laser diode chip with the photo diode chip;
d. bonding the laser diode chip and the photo diode chip to the other pins on the frame by use of conducting wires; and
e. cutting off connected portions among the pins to obtain the laser diode.
